(19) United States
(12) Patent Application Publication
(10) Pub. No.: US 2024/0316594 A1
(43) Pub. Date: Sep. 26, 2024

(54) LAMINATE

(71) Applicant: TOYODA GOSEI CO., LTD., Kiyosu-shi (JP)

(72) Inventors: Yuna SUZUKI, Kiyosu-shi (JP); Koji OKUMURA, Kiyosu-shi (JP); Tsuyoshi SUZUKI, Kiyosu-shi (JP); Yukari ITO, Kiyosu-shi (JP); Kozo HIROTANI, Kiyosu-shi (JP)

(21) Appl. No.: 18/591,157

(22) Filed: Feb. 29, 2024

(30) Foreign Application Priority Data
Mar. 24, 2023 (JP) 2023-048512

(51) Int. Cl. B05D 5/06

(52) U.S. Cl. CPC B05D 5/065; B05D 2201/02; B05D 2430/00; B05D 2601/28

(57) ABSTRACT

A laminate that permits passage of electromagnetic waves includes a base layer made of synthetic resin and a colored layer that contains a filler made of metal. The colored layer permits the passage of electromagnetic waves and has a relative permittivity of 4.0 or greater.

### BACKGROUND

### 1. Field

The present disclosure relates to a laminate that permits the passage of electromagnetic waves.

### 2. Description of Related Art

Japanese Patent No. 4158646 discloses a conventional example of a vehicle component as a laminate. Such a vehicle component includes a base and a coating film. To permit the passage of electromagnetic waves through the vehicle component, it is preferable for the base and the coating film to share the same relative permittivity and have a relative permittivity of 3.0 or less.

When a filler made of metal is contained in the coating film and the relative permittivity of the coating film is set to 3.0 or less so that electromagnetic waves are permitted to pass through the vehicle component, the content of the filler is insufficient. Thus, a coating film having sufficient metallic luster is not formed. As a result, the appearance of the vehicle component may be lowered.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

A laminate according to an aspect of the present disclosure permits passage of electromagnetic waves. The laminate includes a base layer made of synthetic resin and a colored layer that contains a filler made of metal. The colored layer permits the passage of electromagnetic waves and has a relative permittivity of 4.0 or greater.

Other features and aspects will be apparent from the following detailed description, the drawings, and the claims.

### BRIEF DESCRIPTION OF DRAWINGS

FIG. 1 is a schematic cross-sectional view showing a vehicle component according to an embodiment.

FIG. 2 is a schematic diagram of a colored layer of the vehicle component.

FIG. 3 is a graph showing the relationship between the amount of aluminum and the relative permittivity of colored layers A to E.

FIG. 4 is a graph showing the results of deriving the relationship between the thickness of the base layer in each of the vehicle component including colored layer A and the vehicle component including colored layer E and the attenuation amount of millimeter waves that pass through the vehicle component.

FIG. 5 is a graph showing the result of comparing between the attenuation amount of millimeter waves when the thickness of the base layer is optimized and the attenuation amount of millimeter waves when the thickness of the base layer is not optimized in each of the vehicle component including colored layer A and the vehicle component including colored layer E.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the modes, devices, and/or systems described. Modifications and equivalents of the modes, devices, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

A laminate according to an embodiment used as a vehicle component will now be described with reference to the drawings. In the following description, the direction in which a vehicle advances forward will be referred to as the front, and the reverse direction will be referred to as the rear.

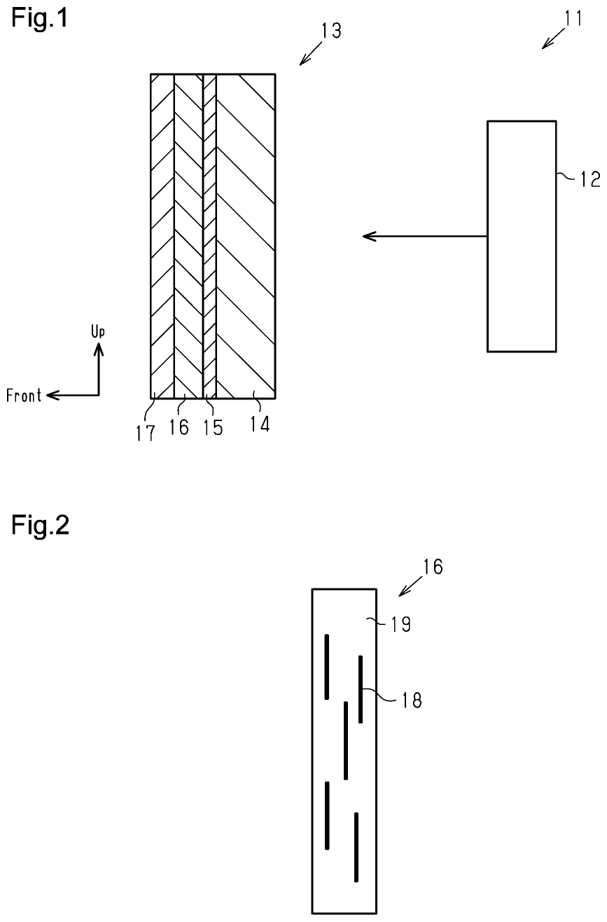

As shown in FIG. 1, a front-monitoring millimeter wave radar device 12 is mounted on the front end of a vehicle 11. The millimeter wave radar device 12 is an example of a radar device that transmits and receives electromagnetic waves. The millimeter wave radar device 12 functions to transmit millimeter waves of electromagnetic waves toward the front of the vehicle 11 and receive the millimeter waves that have struck and have been reflected by an object outside the vehicle 11. Millimeter waves are radio waves each having a wavelength of 1 mm to 10 mm and a frequency of 30 GHz to 300 GHz.

As described above, the millimeter wave radar device 12 transmits millimeter waves toward the front of the vehicle 11. Thus, the direction in which the millimeter wave radar device 12 transmits the millimeter waves coincides with the direction from the rear to the front of the vehicle 11. The front in the transmission direction of millimeter waves substantially matches the front of the vehicle 11. The rear in the transmission direction of millimeter waves substantially matches the rear of the vehicle 11. Thus, in the following description, the front in the transmission direction of millimeter waves is simply referred to as “frontward” or “front,” and the rear in the transmission direction of millimeter waves is simply referred to as “rearward” or “rear.”

### Vehicle Component 13

As shown in FIG. 1, a substantially plate-shaped vehicle component 13 is arranged frontward from the millimeter wave radar device 12. The vehicle component 13 is an example of a laminate that permits the passage of millimeter waves (electromagnetic waves). Examples of the vehicle component 13 include an emblem, a front grille, and a front bumper of the vehicle 11. The vehicle component 13 is arranged upright such that its front surface faces the front of the vehicle 11 and its rear surface faces the rear of the vehicle 11. The front surface of the vehicle component 13 defines an ornamental surface of the vehicle component 13.

The vehicle component 13 includes a base layer 14 made of synthetic resin, a primer layer 15 on the front surface of the base layer 14, a colored layer 16 on the front surface of the primer layer 15, a clear coating layer 17 on the front surface of the colored layer 16. The primer layer 15 is composed of a coating film for undercoating. The clear coating layer 17 is composed of a colorless and transparent top coating film.

### Base Layer 14

As shown in FIG. 1, the base layer 14 is formed into a plate shape by performing, for example, injection-molding using a synthetic resin material that permits the passage of millimeter waves (electromagnetic waves). The synthetic resin material used to form the base layer 14 may be transparent or opaque.

Examples of the synthetic resin material used for forming the base layer 14 include polypropylene (PP) resin, polycarbonate (PC) resin, acrylonitrile-butadiene-styrene (ABS) copolymer resin, acrylonitrile-ethylene-propylene-diene-styrene (AES) resin, polymethyl methacrylate (PMMA) resin, acrylonitrile-styrene-acrylate (ASA) resin, and PMMA resin that includes ASA resin.

### Colored Layer 16

As shown in FIG. 2, the colored layer 16 is formed by dispersing fillers 18 made of metal (aluminum in this example) in a coating film 19 that is used for intermediate coating. That is, the colored layer 16 includes the metal fillers 18. A gap is formed between the fillers 18. Thus, the colored layer 16 permits the passage of millimeter waves (electromagnetic waves). The relative permittivity of the colored layer 16 is set to 4.0 or greater.

Preferably, the thickness of the colored layer 16 is between 3 μm and 75 m, inclusive. More preferably, the thickness of the colored layer 16 is between 5 μm and 75 m, inclusive. If the thickness of the colored layer 16 is less than 3 m, the color of the coating film 19 of the colored layer 16 may be insufficient. If the thickness of the colored layer 16 is greater than 75 m, the ability of the colored layer 16 to permit the passage of millimeter waves may be lowered.

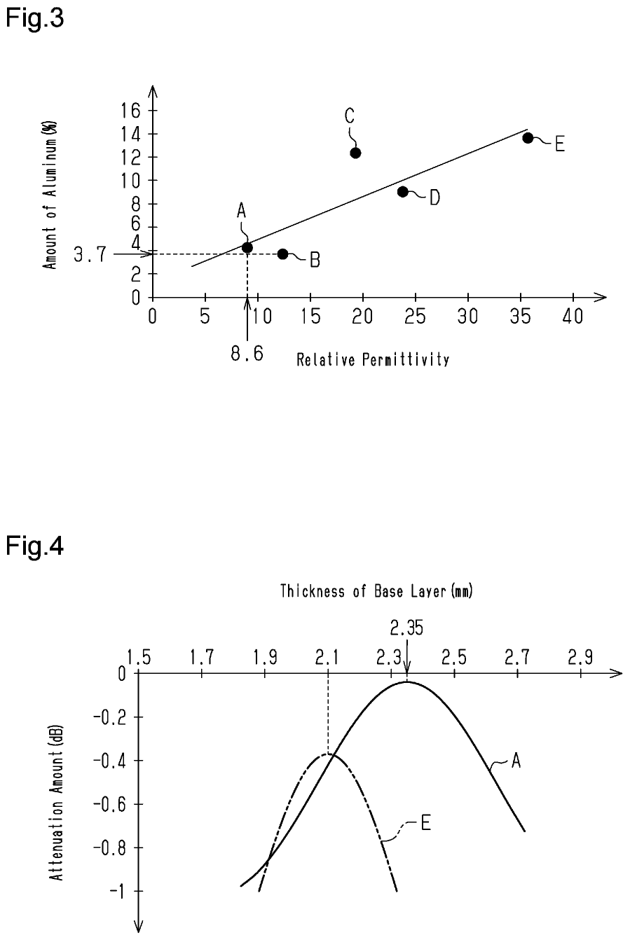

As shown in FIG. 3, the inventors of the present invention found out that there was a positive linear relationship between the amount of aluminum, which is the amount of the fillers 18 contained in the colored layer 16, and the relative permittivity of the colored layer 16. The amount of aluminum contained in the colored layer 16 (the amount of the fillers 18) is expressed by [the weight of aluminum contained in the colored layer 16 (the weight of the fillers 18)/the total weight of the colored layer 16 after being dried)×100%].

FIG. 3 is a graph showing the relationship between the amount of aluminum and the relative permittivity in five colored layers A to E (colored layers 16), each having a coating film 19 in a different color. The graph of FIG. 3 indicates a positive linear relationship between the amount of aluminum contained in the colored layer 16 and the relative permittivity of the colored layer 16.

The graph in FIG. 3 indicates that colored layers A to E are all included in a range in which the amount of aluminum contained (the amount of the fillers 18) is 2.0% or greater and the relative permittivity is 8.0% or greater. Thus, in the vehicle component 13, it is preferable that the amount of aluminum contained in the colored layer 16 be 2.0% or greater and the relative permittivity of the colored layer 16 is 8.0% or greater.

### Setting Thickness of Base Layer 14

Preferably, the thickness of the base layer 14 in the vehicle component 13 is set to between 1.0 mm to 2.5 mm, inclusive. More preferably, the thickness of the base layer 14 in the vehicle component 13 is set to between 2.0 mm to 2.5 mm, inclusive. However, most preferably, the thickness of the base layer 14 is optimized depending on colored layers A to E (refer to FIG. 3) to improve the ability of millimeter waves to pass through the vehicle component 13.

FIG. 4 is a graph showing the results of deriving the relationship between the thickness of the base layer 14 in each of the vehicle component 13 including colored layer A and the vehicle component 13 including colored layer E and the attenuation amount of millimeter waves that pass through the vehicle component 13. The graph of FIG. 4 shows that the optimal thickness of the base layer 14 that has the smallest attenuation amount of millimeter waves in the vehicle component 13 including colored layer A is 2.35 mm. The graph of FIG. 4 shows that the optimal thickness of the base layer 14 that has the smallest attenuation amount of millimeter waves in the vehicle component 13 including colored layer E is 2.10 mm.

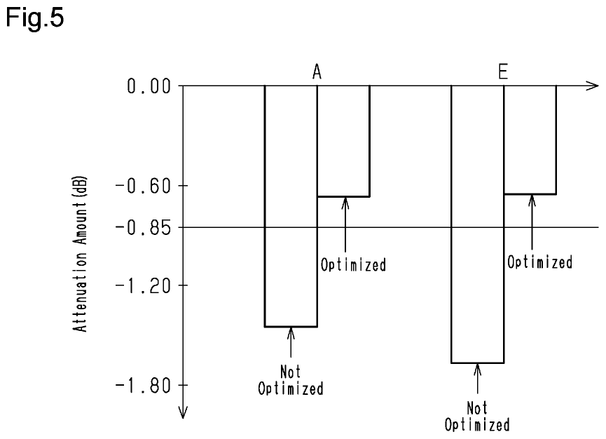

FIG. 5 is a graph showing the results of comparing the attenuation amount of millimeter waves when the thickness of the base layer 14 is optimized and the attenuation amount of millimeter waves when the thickness of the base layer 14 is not optimized in each of the vehicle components 13 including colored layer A and the vehicle components 13 including colored layer E. In FIG. 5, the thickness of the base layer 14 when the optimization is not performed for each of the vehicle component 13 including colored layer A and the vehicle component 13 including colored layer E was both set to 2.5 mm.

In FIG. 5, the thicknesses of the base layers 14 when the optimization is not performed for the vehicle component 13 including colored layer A and the vehicle component 13 including colored layer E were set to 2.35 mm and 2.10 mm, respectively, based on the graph of FIG. 4. The graph of FIG. 5 shows that when the thickness of the base layer 14 is not optimized for both of the vehicle component 13 including colored layer A and the vehicle component 13 including colored layer E, the attenuation amount of millimeter waves is less than −0.85 dB, which is a requested value, and thus does not satisfy the requested value.

The graph of FIG. 5 shows that when the thickness of the base layer 14 is optimized for both of the vehicle component 13 including colored layer A and the vehicle component 13 including colored layer E, the attenuation amount of millimeter waves is greater than or equal to −0.85 dB, which is a requested value, and thus satisfies the requested value. Thus, in the vehicle component 13, the thickness of the base layer 14 is optimized depending on the color of the coating film 19 of the selected colored layer 16 to minimize the attenuation amount of millimeter waves.

### Operation of Vehicle Component 13

When millimeter waves are transmitted from the millimeter wave radar device 12 shown in FIG. 1, the millimeter waves pass through the layers of the vehicle component 13. The millimeter waves that have passed through strike and are reflected by an object outside the vehicle 11 including, for example, a vehicle leading that vehicle and pedestrians. Then, the millimeter waves again pass through the layers of the vehicle component 13 and are received by the millimeter wave radar device 12.

In this case, the colored layer 16 of the vehicle component 13 permits the passage of millimeter waves. Additionally, in the vehicle component 13, since the relative permittivity of the colored layer 16 is 4.0 or greater, the content of the fillers 18 in the colored layer 16 increases. Thus, the appearance of the vehicle component 13 is improved. This permits the passage of millimeter waves through the vehicle component 13 and improves the appearance of the vehicle component 13.

Based on the transmitted and received millimeter waves, the millimeter wave radar device 12 recognizes an object and detects the distance between the object and the vehicle 11, the relative speed, and the like.

### Advantages of Embodiment

The embodiment described above in detail has the following advantages.

(1) The vehicle component 13 includes the base layer 14, which is made of synthetic resin, and the colored layer 16, which is formed by dispersing the aluminum fillers 18 in the coating film 19. The colored layer 16 permits the passage of millimeter waves and has a relative permittivity of 4.0 or greater.

The inventors of the present invention found out that the amount of the fillers 18 contained in the colored layer 16 [(the weight of the fillers 18 contained in the colored layer 16/the total weight of the colored layer 16 after being dried)×100%] had a positive linear relationship with the relative permittivity of the colored layer 16. Thus, in this configuration, the relative permittivity of the colored layer 16, which permits the passage of millimeter waves, is set to 4.0 or greater so that the content of the fillers 18 in the colored layer 16 increases. Thus, the appearance of the vehicle component 13 is improved. This improves the appearance of the vehicle component 13 while permitting the passage of millimeter waves through the vehicle component 13. That is, the configuration permits the passage of millimeter waves through the vehicle component 13 and improves the appearance of the vehicle component 13.

(2) In the vehicle component 13, the thickness of the colored layer 16 is between 3 μm to 75 μm, inclusive.

In this configuration, the thickness of the colored layer 16 is set to 75 μm or less. Thus, even if the colored layer 16 having a relative permittivity of 4.0 or greater is used as the vehicle component 13, sufficient passage of millimeter waves through the vehicle component 13 is ensured. When the thickness of the colored layer 16 is set to 3 μm or greater, the color of the coating film 19 is maintained. Thus, a favorable appearance of the vehicle component 13 is maintained. This maintains a favorable appearance of the vehicle component 13 while ensuring sufficient passage of millimeter waves through the vehicle component 13.

(3) In the vehicle component 13, the amount of the fillers 18 contained in the colored layer 16 is 2.0% or greater, and the relative permittivity of the colored layer 16 is 8.0 or greater.

In this configuration, the amount of the fillers 18 contained in the colored layer 16 is further increased by setting the amount of the fillers 18 contained in the colored layer 16 to 2.0% or greater and setting the relative permittivity of the colored layer 16 to 8.0 or greater.

This further improves the appearance of the vehicle component 13.

### Modifications

The above embodiment may be modified as follows. The above embodiment and the following modifications can be combined as long as the combined modifications remain technically consistent with each other.

The colored layer 16 may be formed using a film of transparent resin with multiple fillers 18 and paints. This allows the colored layer 16 to directly adhere to the base layer 14 of the vehicle component 13. Thus, the primer layer 15 and the clear coating layer 17 may be omitted.

The colored layer 16 may include a coloring agent such as dye.

In the vehicle component 13, the amount of the fillers 18 contained in the colored layer 16 does not have to be 2.0% or greater, and the relative permittivity of the colored layer 16 does not have to be 8.0 or greater.

In the vehicle component 13, the thickness of the colored layer 16 does not have to be between 3 μm to 75 μm, inclusive.

The millimeter wave radar device 12, which transmits and receives millimeter waves (electromagnetic waves) used to detect an object outside the vehicle, does not have to be a front-monitoring device, any may be a rear-monitoring device.

The radar device may be an infrared radar device that transmits and receives infrared rays (electromagnetic waves).

The laminate is not limited to the vehicle component 13 and may also be used for a part for a consumer product. That is, the laminate may be used for a part for a consumer product, other than the vehicle 11, that incorporates a radar device that transmits and receives electromagnetic waves. Examples of such a part for a consumer product include an automatic cleaning robot, a transport robot, a serving robot, and a drone.

Preferably, when the laminate is a part for a consumer product having the same layer structure as the vehicle component 13, the thickness of the base layer 14 is preferably set to between 1.0 mm to 2.5 mm, inclusive, and the thickness of the colored layer 16 is set to 3 μm to 75 μm, inclusive.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. A laminate that permits passage of electromagnetic waves, the laminate comprising:
a base layer made of synthetic resin; and
a colored layer that contains a filler made of metal, wherein
the colored layer permits the passage of electromagnetic waves and has a relative permittivity of 4.0 or greater.

2. The laminate according to claim 1, wherein
a thickness of the colored layer is between 3 μm to 75 μm, inclusive.

3. The laminate according to claim 2, wherein
an amount of the filler contained in the colored layer is 2.0% or greater, and the relative permittivity of the colored layer is greater than or equal to 8.0.
